(19) United States
(12) Patent Application Publication
(10) Pub. No.: US 2024/0266289 A1
(43) Pub. Date: Aug. 8, 2024

(54) SEMICONDUCTOR STRUCTURE AND METHOD OF FORMING SEMICONDUCTOR STRUCTURE

(71) Applicant: Semiconductor Manufacturing International (Shanghai) Corporation, Shanghai (CN)

(72) Inventor: Jisong JIN, Shanghai (CN)

(21) Appl. No.: 18/431,007

(22) Filed: Feb. 2, 2024

(30) Foreign Application Priority Data
Feb. 3, 2023 (CN) 202310095473.3

(51) Int. Cl. H01L 23/528; H01L 21/768

(52) U.S. Cl. CPC H01L 23/5286; H01L 21/768

(57) ABSTRACT

Semiconductor structure and forming method thereof are provided. The method includes providing a substrate. The substrate includes a first side and a second side, and the substrate includes a first region and a second region. The method also includes forming a device layer over the first side of the first region, where the device layer includes a device structure; forming a first electrical connection structure over the device layer; forming a second electrical connection structure over the first side of the second region; and forming a first connecting structure in in the first region. The method also includes forming a third electrical connection structure over the second side of the first region; and forming a second connecting structure in the second region. The second connecting structure is electrically connected to the third electrical connection structure, and the second connecting structure is electrically connected to the second electrical connection structure.

### CROSS-REFERENCE TO RELATED APPLICATION

This application claims priority of Chinese Patent Application No. 202310095473.3, filed on Feb. 3, 2023, the entire content of which is hereby incorporated by reference.

### FIELD OF THE DISCLOSURE

The present disclosure generally relates to the field of semiconductor manufacturing and, more particularly, relates to a semiconductor structure and a method of forming the semiconductor structure.

### BACKGROUND

With improvement of nodes in semiconductor technology, dimensions of semiconductor structures are getting smaller and smaller, and integration levels are getting higher and higher. As such, a backside power distribution network (BPDN) is often used to rationally utilize a backside area of a wafer to achieve further miniaturization. A backside electrical connection network of a wafer may be electrically connected to devices over a front side of the wafer through a buried power rail (BPR) that runs through the wafer.

However, improvement is still needed for a semiconductor structure with a buried power rail and a backside electrical connection network.

### BRIEF SUMMARY OF THE DISCLOSURE

One aspect of the present disclosure includes a method of forming a semiconductor structure. The method includes providing a substrate. The substrate includes a first side and a second side opposite to the first side, and the substrate includes a first region and a second region. The method also includes forming a device layer over the first side of the first region, where the device layer includes a device structure within the device layer, forming a first electrical connection structure over the device layer, where the first electrical connection structure is electrically connected to the device structure, forming a second electrical connection structure over the first side of the second region, and forming a first connecting structure in in the first region. The first connecting structure penetrates the substrate, and the first connecting structure is electrically connected to the device structure. The method also includes forming a third electrical connection structure over the second side of the first region, where the third electrical connection structure is electrically connected to the first connecting structure, and forming a second connecting structure in the second region. The second connecting structure is electrically connected to the third electrical connection structure, the second connecting structure extends from the second side to the first side, the second connecting structure penetrates the substrate and the device layer, and the second connecting structure is electrically connected to the second electrical connection structure.

Optionally, the device layer includes an isolation structure and the device structure located within the isolation structure. The device structure includes a transistor, a capacitor or an inductor, and the isolation structure is also located over the first side of the second region.

Optionally, the method also includes forming a first dielectric structure over the isolation structure. The first electrical connection structure and the second electrical connection structure are located within the first dielectric structure.

Optionally, the method also includes forming a second dielectric structure over the second surface of the substrate. The third electrical connection structure is located within the second dielectric structure. The second connecting structure penetrates the second dielectric structure, the second region, the isolation structure and part of the first dielectric structure.

Optionally, the method also includes forming a fourth electrical connection structure over the second dielectric structure. The fourth electrical connection structure includes a fourth plug and a fourth metal layer located over the fourth plug. The fourth plug is in contact with the third electrical connection structure. The second connecting structure is in contact with the fourth metal layer.

Optionally, a process of forming the second connecting structure and the fourth electrical connection structure includes: after forming the third electrical connection structure, forming a third dielectric structure over the second dielectric structure; forming a third groove in the third dielectric structure, the second dielectric structure, the second region, the device layer, and part of the first dielectric structure, where a bottom of the third groove exposes a bottom surface of the second electrical connection structure; forming the second connecting structure in the third groove; forming the fourth plug in the third dielectric structure; and forming the fourth metal layer over the fourth plug and the second connecting structure.

Optionally, the third electrical connection structure includes a plurality of layers of third plugs and a plurality of layers of third metal layers, and the plurality of layers of third plugs and the plurality of layers of third metal layers are alternately arranged.

Optionally, the first electrical connection structure includes a plurality of layers of first plugs and a plurality of layers of first metal layers, and the plurality of layers of first plugs and the plurality of layers of first metal layers are alternately arranged; the second electrical connection structure includes a plurality of layers of second metal layers and a second plug located between second metal layers of the plurality of layers of second metal layers; and the second connecting structure is electrically connected to a second metal layer of the plurality of layers of second metal layers.

Optionally, the substrate includes a base and a fin structure located over the base.

Optionally, the first connecting structure includes a first portion and a second portion in contact with the first portion; the first portion extends from the first side of the substrate to the second side of the substrate; a bottom of the first portion is located in the first region, and a top of the first portion is located in the device layer; and the second portion extends from the second side of the substrate to the first side of the substrate.

Optionally, a process of forming the first connecting structure includes: after forming the device layer, forming a first groove in the device layer and the first region, where the first groove extends from the first side of the substrate to the second side of the substrate, and a bottom of the first groove is located in the first region; forming the first portion within the first groove; after forming the first portion, forming the first electrical connection structure over the device layer, where the first electrical connection structure is electrically connected to the first portion; after forming the first electrical connection structure and the second electrical connection structure, forming a second groove in the first region, where the second groove extends from the second side of the substrate to the first side of the substrate, a bottom of the second groove exposes a bottom surface of the first portion; and forming the second portion in the second groove.

Another aspect of the present disclosure includes a semiconductor structure. A semiconductor structure includes a substrate, where the substrate includes a first side and a second side opposite to the first side, and the substrate includes a first region and a second region; a device layer located over the first side of the first region, where the device layer includes a device structure; a first electrical connection structure located over the device layer, where the first electrical connection structure is electrically connected to the device structure; a second electrical connection structure located over the first side of the second region; a first connecting structure located in the first region, where the first connecting structure penetrates the substrate and is electrically connected to the device structure; a third electrical connection structure located on the second side of the first region, where the third electrical connection structure is electrically connected to the first connecting structure; and a second connecting structure located in the second region. The second connecting structure is electrically connected to the third electrical connection structure, the second connecting structure extends from the second side of the substrate to the first side of the substrate, the second connecting structure penetrates the substrate and the device layer, and the second connecting structure is electrically connected to the second electrical connection structure.

Optionally, the device layer includes an isolation structure and the device structure located within the isolation structure, where the device structure includes a transistor, a capacitor, or an inductor; and the isolation structure is also located over the first side of the second region.

Optionally, the semiconductor structure also includes a first dielectric structure located over the isolation structure, where the first electrical connection structure and the second electrical connection structure are located in the first dielectric structure; and a second dielectric structure located over the second side of the substrate, where the third electrical connection structure is located within the second dielectric structure, the second connecting structure penetrates the second dielectric structure, the substrate, the device layer, and part of the first dielectric structure.

Optionally, the semiconductor structure also includes a fourth electrical connection structure located over the second dielectric structure. The fourth electrical connection structure includes a fourth plug and a fourth metal layer located over the fourth plug; the fourth plug is in contact with the third electrical connection structure; and the second connecting structure is in contact with the fourth metal layer.

Optionally, the third electrical connection structure includes a plurality of layers of third plugs and a plurality of layers of third metal layers, and the plurality of layers of the third plugs and the plurality of layers of the third metal layers are alternately arranged.

Optionally, the first electrical connection structure includes a plurality of layers of first plugs and a plurality of layers of first metal layers, and the plurality of layers of the first plugs and the plurality of layers of the first metal layers are alternately arranged; the second electrical connection structure includes a plurality of layers of second metal layers and a second plug located between second metal layers of the plurality of layers of second metal layers; and the second connecting structure is electrically connected to a second metal layer of the plurality of layers of second metal layers.

Optionally, the substrate includes a base and a fin structure located over the base.

Optionally, the first connecting structure includes a first portion and a second portion in contact with the first portion; the first portion extends from the first side of the substrate to the second side of the substrate, a bottom of the first portion is located in the first region, and a top of the first portion is located in the device layer; and the second portion extends from the second side of the substrate to the first side of the substrate.

Optionally, the first connecting structure is made of a material including metal or metal nitride; the second connecting structure is made of a material including metal or metal nitride; the metal includes copper, aluminum, tungsten, cobalt, nickel, tantalum, or a combination thereof; and the metal nitride includes tantalum nitride, titanium nitride, or a combination thereof.

As disclosed, the technical solutions of the present disclosure have the following advantages.

In the present disclosure, a second connecting structure is formed in the second region. The second electrical connection structure over the first side of the substrate may be electrically connected to the third electrical connection structure over the second side of the substrate through the second connecting structure. Accordingly, the third electrical connection structure on the second side of the substrate may be connected to an external circuit through the second electrical connection structure over the first side. As such, when the semiconductor structure is subsequently packaged, no complicated packaging process is required, provided that a connection interface is provided for the first electrical connection structure and the second electrical connection structure over the first side of the substrate. A conventional packaging process may be used for packaging. Accordingly, the packaging process may be simplified, and manufacturing costs may be reduced.

### BRIEF DESCRIPTION OF THE DRAWINGS

The following drawings are merely examples for illustrative purposes according to various disclosed embodiments and are not intended to limit the scope of the present disclosure.

FIG. 1 illustrates a schematic diagram of a semiconductor structure;

FIGS. 2 to 8 illustrate schematic structural diagrams corresponding to certain stages of an exemplary process of forming a semiconductor structure, consistent with the disclosed embodiments of the present disclosure; and

FIG. 9 illustrates a flowchart of an exemplary process of forming a semiconductor structure, consistent with the disclosed embodiments of the present disclosure.

### DETAILED DESCRIPTION

To make the objectives, technical solutions and advantages of the present disclosure clearer and more explicit, the present disclosure is described in further detail with accompanying drawings and embodiments. It should be understood that the specific exemplary embodiments described herein are only for explaining the present disclosure and are not intended to limit the present disclosure.

Reference will now be made in detail to exemplary embodiments of the present disclosure, which are illustrated in the accompanying drawings. Wherever possible, the same reference numbers will be used throughout the drawings to refer to the same or like parts.

Improvement is still needed for a semiconductor structure with a buried power rail and a backside electrical connection network. Analysis and description will now be carried out with reference to specific embodiments.

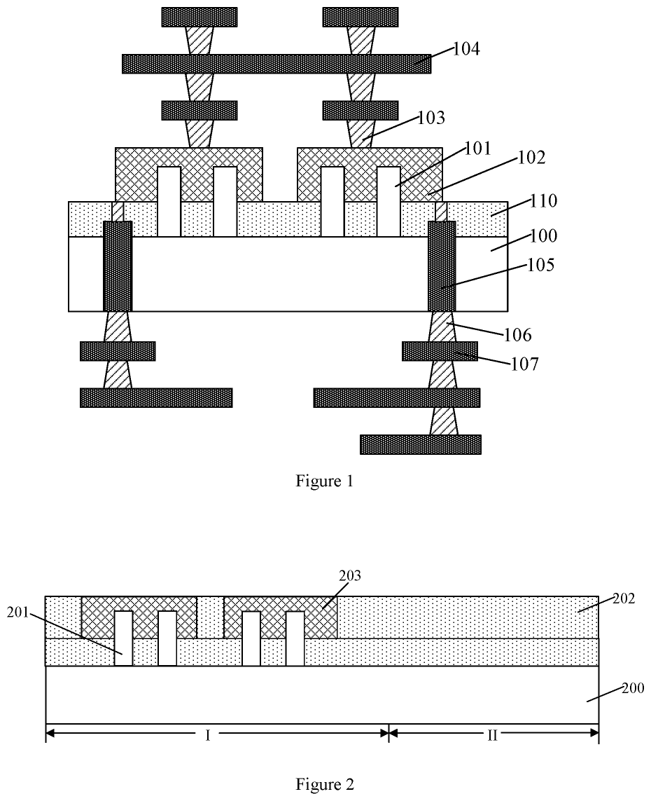

FIG. 1 illustrates a schematic diagram of a semiconductor structure. Referring to FIG. 1, the semiconductor structure includes: a substrate 100, where the substrate 100 includes a first side and a second side opposite to the first side; a fin structure 101 located over the first side of the substrate 100; an isolation layer 110 located over the first side of the substrate 100; a gate structure 102 spanning the fin structure 101, where the gate structure 102 is located over the isolation layer 110; a first electrical connection structure located over the gate structure 102. The first electrical connection structure includes a plurality of layers of first plugs 103 and a plurality of layers of first metal layers 104. The plurality of layers of the first plugs 103 and the plurality of layers of the first metal layers 104 are arranged alternately. The semiconductor structure also includes a connecting structure 105 located in the substrate 100. The connecting structure 105 penetrates the substrate 100 and is electrically connected to the gate structure 102. The semiconductor structure also includes a second electrical connection structure located on the second side of the substrate 100. The second electrical connection structure includes a plurality of second metal layers 107 and second plugs 106 located between the plurality of second metal layers 107. The second plugs 106 are electrically connected to the connecting structure 105.

In the semiconductor structure, the first side of the substrate 100 has a first electrical connection structure, and the second side of the substrate 100 has a second electrical connection structure. The first electrical connection structure and the second electrical connection structure each need to be connected to external circuits. Accordingly, during subsequent packaging, a complex packaging structure may be required to achieve double-sided power supply for the semiconductor structure. The packaging process may be complex, and the implementation cost may be high.

To solve the above problems, the present disclosure provides a semiconductor structure and a method of forming the semiconductor structure. A second connecting structure is formed in the second region. The second electrical connection structure over the first side of the substrate may be electrically connected to the third electrical connection structure over the second side of the substrate through the second connecting structure. Accordingly, the third electrical connection structure on the second side of the substrate may be connected to an external circuit through the second electrical connection structure over the first side. As such, when the semiconductor structure is subsequently packaged, no complicated packaging process is required, provided that a connection interface is provided for the first electrical connection structure and the second electrical connection structure over the first side of the substrate. A conventional packaging process may be used for packaging. Accordingly, the packaging process may be simplified, and manufacturing costs may be reduced.

To make the above objects, features and beneficial effects of the present disclosure obvious and understandable, specific embodiments of the present disclosure will be described below with reference to the accompanying drawings.

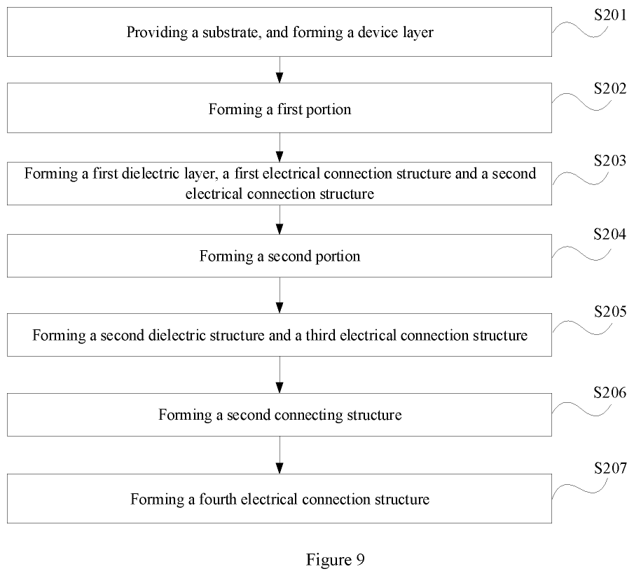

FIG. 9 illustrates a flowchart of an exemplary process of forming a semiconductor structure, consistent with the disclosed embodiments of the present disclosure. FIGS. 2 to 8 illustrate schematic structural diagrams corresponding to certain stages of an exemplary process of forming a semiconductor structure, consistent with the disclosed embodiments of the present disclosure.

As shown in FIG. 9, at the beginning of the forming process, a substrate is provided, followed by forming a device layer (S201). FIG. 2 illustrates a corresponding semiconductor structure.

Referring to FIG. 2, a substrate is provided. The substrate includes a first side and a second side opposite to the first side. The substrate includes a first region I and a second region II.

In one embodiment, the substrate includes a base 200 and a fin structure 201 located over the base 200. In one embodiment, the base 200 and the fin structure 201 are made of silicon. In some other embodiments, the base and the fin structure may be made of a material including silicon carbide, silicon germanium, a multi-element semiconductor material composed of group III-V elements, silicon on insulator (SOI), germanium on insulator (GOI), or a combination thereof. The multi-element semiconductor material composed of III-V group elements may include InP, GaAs, GaP, InAs, InSb, InGaAs, InGaAsP, or a combination thereof.

In some other embodiments, the substrate may include a planar substrate.

Still referring to FIG. 2, a device layer may be formed over the first side of the first region I. The device layer may include a device structure within the device layer. The device layer may include an isolation structure 202 and a device structure located within the isolation structure 202. The device structure may include a transistor, a capacitor or an inductor. The isolation structure 202 may also be located on the first side of the second region II.

In one embodiment, the device structure includes a transistor. The transistor includes a gate structure 203 spanning the fin structure 201, and a source/drain doped region (not shown) located in the fin structure 201 on two sides of the gate structure 203.

In one embodiment, the isolation structure 202 may include a first isolation layer (not labeled) and a second isolation layer (not labeled) located over the first isolation layer. The first isolation layer is located on the sidewall surface of the fin structure 201 and is lower than a top surface of the fin structure 201. The gate structure 203 is located over the first isolation layer, and the gate structure 203 is located within the second isolation layer.

The isolation structure 202 may be made of a material including a dielectric material. The dielectric material may include silicon oxide, silicon nitride, silicon carbide, silicon oxycarbide, silicon oxynitride, aluminum oxide, aluminum nitride, silicon oxynitride, silicon oxynitride, or a combination thereof. In one embodiment, the isolation structure 202 is made of a material including silicon oxide.

In one embodiment, the device structure may be only disposed in the first region I. In some other embodiments, the device structure may also be disposed in the second region. The density of the device structure in the first region may be greater than the density of the device structure in the second region, such that a second connecting structure may pass through the second region.

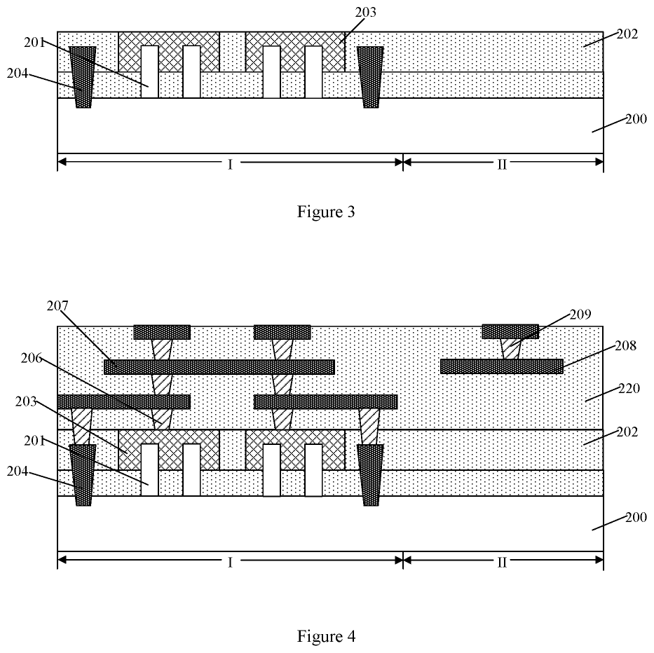

A first electrical connection structure may then be formed on the device layer. The first electrical connection structure is electrically connected to the device structure. A first connecting structure may be formed in the first region I. The first connecting structure penetrates the substrate and is electrically connected to the device structure. FIGS. 3 to 5 illustrate a process of forming the first electrical connection structure and the first connecting structure.

The first connecting structure includes a first portion and a second portion in contact with the first portion. The first portion extends from the first side to the second side of the substrate. The bottom of the first portion is located in the first region I. The top of the first portion is located in the device layer. The second portion extends from the second side of the substrate to the first side.

Returning to FIG. 9, after providing the substrate and forming the device layer, a first portion may be formed (S202). FIG. 3 illustrates a corresponding semiconductor structure.

Referring to FIG. 3, a first groove (not shown) is formed in the device layer and the first region I. The first groove extends from the first side to the second side of the substrate, and the bottom of the first groove is located in the first region I. The first portion 204 is formed within the first groove.

In one embodiment, the bottom of the first portion is located in the first region I, and the top of the first portion is located in the isolation structure 202.

The first portion 204 may be made of a material including metal or metal nitride. The metal may include copper, aluminum, tungsten, cobalt, nickel, tantalum, or a combination thereof. The metal nitride may include tantalum nitride, titanium nitride, or a combination thereof.

Returning to FIG. 9, after forming the first portion, a first dielectric layer, a first electrical connection structure and a second electrical connection structure may be formed (S203). FIG. 4 illustrates a corresponding semiconductor structure.

Referring to FIG. 4, a first dielectric structure 220 over the device layer and a first electrical connection structure in the first dielectric structure 220 over the first region I may be formed. The first electrical connection structure is electrically connected to the device structure, and the first electrical connection structure is electrically connected to the first portion 204.

The first portion 204 is electrically connected to the device structure through a first electrical connection structure. The first electrical connection structure includes a plurality of layers of first plugs 206 and a plurality of layers of first metal layers 207. The plurality of layers of first plugs 206 and the plurality of layers of first metal layers 207 are alternately arranged. In one embodiment, the first plug 206 is electrically connected to the gate structure 203.

The first electrical connection structure may be made of a material including metal or metal nitride. The metal may include copper, aluminum, tungsten, cobalt, nickel, tantalum, or a combination thereof. The metal nitride may include tantalum nitride, titanium nitride, or a combination thereof.

The first dielectric structure 220 may be made of a material including a dielectric material. The dielectric material may include silicon oxide, silicon nitride, silicon carbide, silicon oxycarbide, silicon oxynitride, aluminum oxide, aluminum nitride, silicon oxynitride, silicon oxynitride, or a combination thereof. In one embodiment, the first dielectric structure 220 is made of a material including silicon oxide.

Still referring to FIG. 4, while the first electrical connection structure is formed, a second electrical connection structure may be formed in the first dielectric structure 220 over the second region II. The second electrical connection structure includes a plurality of second metal layers 208 and a second plug 209 located between the second metal layers 208. The second electrical connection structure and the first electrical connection structure may be formed using one process.

The second electrical connection structure may be made of a material including metal or metal nitride. The metal may include copper, aluminum, tungsten, cobalt, nickel, tantalum, or a combination thereof. The metal nitride may include tantalum nitride, titanium nitride, or combination thereof.

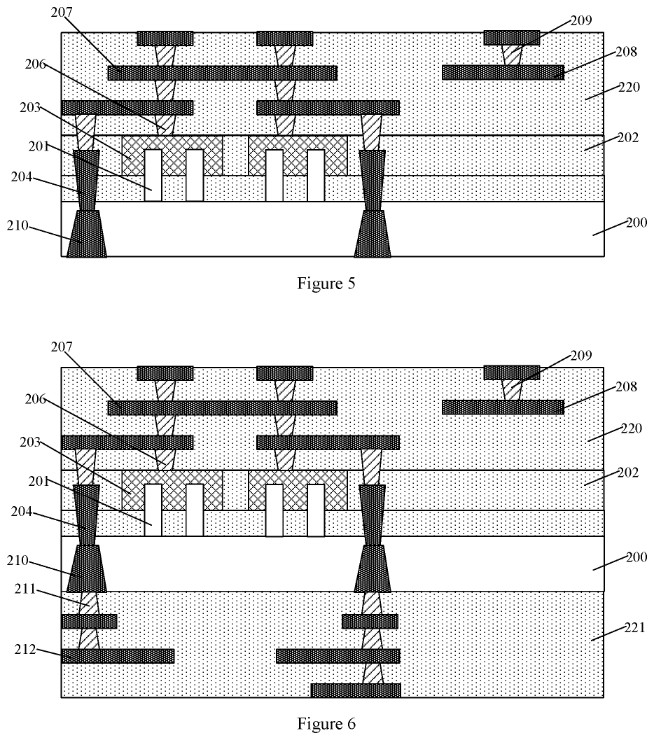

Returning to FIG. 9, after forming the first dielectric layer, the first electrical connection structure and the second electrical connection structure, a second portion may be formed (S204). FIG. 5 illustrates a corresponding semiconductor structure.

Referring to FIG. 5, a second groove (not shown) may be formed in the first region I. The second groove extends from the second side of the substrate to the first side. The bottom of the second groove exposes the bottom surface of the first portion 204. A second portion 210 is formed in the second groove. The second portion 210 is in contact with the first portion 204.

The second portion 210 may be made of a material including metal or metal nitride. The metal may include copper, aluminum, tungsten, cobalt, nickel, tantalum, or a combination thereof. The metal nitride may include tantalum nitride, titanium nitride, or a combination thereof.

Returning to FIG. 9, after forming the second portion, a second dielectric structure and a third electrical connection structure may be formed (S205). FIG. 6 illustrates a corresponding semiconductor structure.

Referring to FIG. 6, a second dielectric structure 221 and a third electrical connection structure located in the second dielectric structure 221 may be formed on the second side of the first region I. The third electrical connection structure is electrically connected to the first connecting structure.

The third electrical connection structure includes a plurality of layers of third plugs 211 and a plurality of layers of third metal layers 212. The plurality of layers of third plugs 211 and the plurality of layers of third metal layers 212 are arranged alternately. The third plug 211 is electrically connected to the second portion 210.

The third electrical connection structure may be made of a material including metal or metal nitride. The metal may include copper, aluminum, tungsten, cobalt, nickel, tantalum, or a combination thereof. The metal nitride may include tantalum nitride, titanium nitride, or a combination thereof.

The second dielectric structure 221 may be made of a material including a dielectric material. The dielectric material may include silicon oxide, silicon nitride, silicon carbide, silicon oxycarbide, silicon oxynitride, aluminum oxide, aluminum nitride, silicon oxynitride, silicon oxynitride, or a combination thereof. In one embodiment, the second dielectric structure 221 is made of a material including silicon oxide.

A second connecting structure may then be formed in the second region II. The second connecting structure is electrically connected to the third electrical connection structure. The second connecting structure extends from the second side of the substrate to the first side. The second connecting structure penetrates the substrate and the device layer and is electrically connected to the second electrical connection structure.

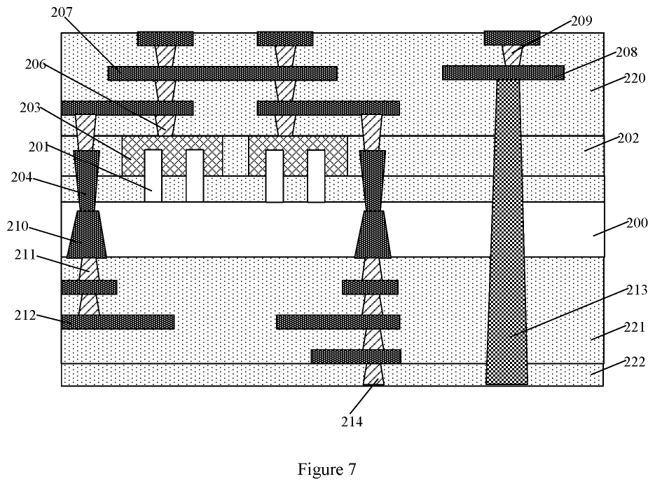

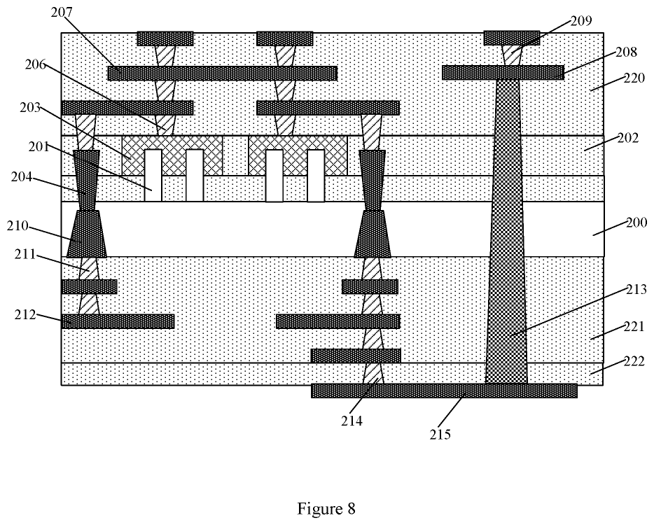

In one embodiment, the method also includes forming a fourth electrical connection structure on the second dielectric structure. The second connecting structure is electrically connected to the third electrical connection structure through a fourth electrical connection structure. FIGS. 7 and 8 show a process of forming the fourth electrical connection structure and the third electrical connection structure.

The fourth electrical connection structure includes a fourth plug and a fourth metal layer located over the fourth plug.

Returning to FIG. 9, after forming the second dielectric structure and the third electrical connection structure, a second connecting structure may be formed (S206). FIG. 7 illustrates a corresponding semiconductor structure.

Referring to FIG. 7, a third dielectric structure 222 may be formed over the second dielectric structure 221. A fourth plug 214 may be formed in the third dielectric structure 222, and the fourth plug 214 is in contact with the third electrical connection structure. A third groove (not shown) may be formed in the third dielectric structure 222, the second dielectric structure 221, the second region II, the isolation structure 202, and part of the first dielectric structure 220. The bottom of the third groove exposes the bottom surface of the second electrical connection structure. The second connecting structure 213 may be formed in the third groove. The second connecting structure 213 penetrates the third dielectric structure 222, the second dielectric structure 221, the second region II, the isolation structure 202 and part of the first dielectric structure 220.

In one embodiment, the fourth plug 214 is in contact with the third metal layer 212, and the second connecting structure 213 is in contact with the second metal layer 208.

The second connecting structure 213 may be made of a material including metal or metal nitride. The metal may include copper, aluminum, tungsten, cobalt, nickel, tantalum, or a combination thereof. The metal nitride may include tantalum nitride, titanium nitride, or a combination thereof.

Returning to FIG. 9, after forming the second connecting structure, a fourth electrical connection structure may be formed (S207). FIG. 8 illustrates a corresponding semiconductor structure.

Referring to FIG. 8, a fourth metal layer 215 may be formed over the fourth plug 214 and the second connecting structure 213 to form the fourth electrical connection structure.

The fourth electrical connection structure may be made of a material including metal or metal nitride. The metal may include copper, aluminum, tungsten, cobalt, nickel, tantalum, or a combination thereof. The metal nitride may include tantalum nitride, titanium nitride, or a combination thereof.

In the present disclosure, a second connecting structure 213 is formed in the second region II. The second electrical connection structure over the first side of the substrate may be electrically connected to the third electrical connection structure over the second side of the substrate through the second connecting structure 213. Accordingly, the third electrical connection structure on the second side of the substrate may be connected to an external circuit through the second electrical connection structure over the first side. As such, when the semiconductor structure is subsequently packaged, no complicated packaging process is required, provided that a connection interface is provided for the first electrical connection structure and the second electrical connection structure over the first side of the substrate. A conventional packaging process may be used for packaging. Accordingly, the packaging process may be simplified, and manufacturing costs may be reduced.

A process of packaging the semiconductor structure includes: providing a packaging substrate, where the packaging substrate includes a third side and a fourth side opposite to the third side; fixedly connecting the semiconductor structure to the third side of the packaging substrate, where the first electrical connection structure and the second electrical connection structure face the third side of the packaging substrate; forming an insulating layer on the third side of the packaging substrate, where the insulating layer covers the semiconductor structure; and forming a plurality of pins on the fourth side of the packaging substrate, where the plurality of pins is electrically connected to the first electrical connection structure or the second electrical connection structure.

The present disclosure also provides a semiconductor structure. Referring to FIG. 8, the semiconductor structure includes:
a substrate, where the substrate includes a first side and a second side opposite to the first side, and the substrate includes a first region I and a second region II;
a device layer located over the first side of the first region I, where the device layer includes a device structure;
a first electrical connection structure located over the device layer, where the first electrical connection structure is electrically connected to the device structure;
a second electrical connection structure located over the first side of the second region II;
a first connecting structure located in the first region I, where the first connecting structure penetrates the substrate and is electrically connected to the device structure;
a third electrical connection structure located on the second side of the first region I, where the third electrical connection structure is electrically connected to the first connecting structure; and
a second connecting structure 213 located in the second region II, where the second connecting structure 213 is electrically connected to the third electrical connection structure, the second connecting structure 213 extends from the second side of the substrate to the first side, and the second connecting structure 213 penetrates the substrate and the device layer and is electrically connected to the second electrical connection structure.

In one embodiment, the device layer includes an isolation structure 202 and a device structure located within the isolation structure 202. The device structure may include a transistor, a capacitor, or an inductor. The isolation structure is also located on the first side of the second region II.

In one embodiment, the semiconductor structure also includes a first dielectric structure 220 located over the isolation structure 202. The first electrical connection structure and the second electrical connection structure are located in the first dielectric structure 220. The semiconductor structure also includes a second dielectric structure 221 located over the second side of the substrate. The third electrical connection structure is located within the second dielectric structure 221. The second connecting structure 213 penetrates the second dielectric structure 221, the substrate, the device layer, and part of the first dielectric structure 220.

In one embodiment, the semiconductor also includes a fourth electrical connection structure located over the second dielectric structure 221. The fourth electrical connection structure includes a fourth plug 214 and a fourth metal layer 215 located over the fourth plug 214. The fourth plug 214 is in contact with the third electrical connection structure, and the second connecting structure 213 is in contact with the fourth metal layer 215.

In one embodiment, the third electrical connection structure includes a plurality of layers of third plugs 211 and a plurality of layers of third metal layers 212. The plurality of layers of the third plugs 211 and the plurality of layers of the third metal layers 212 are arranged alternately.

In one embodiment, the first electrical connection structure includes a plurality of layers of first plugs 206 and a plurality of layers of first metal layers 207. The plurality of layers of the first plugs 206 and the plurality of layers of the first metal layers 207 are arranged alternately. The second electrical connection structure includes a plurality of second metal layers 208 and second plugs 209 located between the plurality of second metal layers 208. The second connecting structure 213 is electrically connected to the second metal layer 208.

In one embodiment, the substrate includes a base 200 and a fin structure 201 located over the base 200.

In one embodiment, the first connecting structure includes a first portion 204 and a second portion 210 in contact with the first portion 204. The first portion 204 extends from the first side to the second side of the substrate. The bottom of the first portion 204 is located in the first region I. The top of the first portion 204 is located within the device layer. The second portion 210 extends from the second side of the substrate to the first side.

In one embodiment, the first connecting structure may be made of a material including metal or metal nitride. The second connecting structure 213 may be made of a material including metal or metal nitride. The metal may include copper, aluminum, tungsten, cobalt, nickel, tantalum, or a combination thereof. The metal nitride may include tantalum nitride, titanium nitride, or a combination thereof.

The embodiments disclosed in the present disclosure are exemplary only and not limiting the scope of the present disclosure. Various combinations, alternations, modifications, or equivalents to the technical solutions of the disclosed embodiments can be obvious to those skilled in the art and can be included in the present disclosure. Without departing from the spirit of the present disclosure, the technical solutions of the present disclosure may be implemented by other embodiments, and such other embodiments are intended to be encompassed within the scope of the present disclosure.

What is claimed is:

1. A method of forming a semiconductor structure, comprising:
providing a substrate, wherein the substrate includes a first side and a second side opposite to the first side, and the substrate includes a first region and a second region;
forming a device layer over the first side of the first region, wherein the device layer includes a device structure within the device layer;
forming a first electrical connection structure over the device layer, wherein the first electrical connection structure is electrically connected to the device structure;
forming a second electrical connection structure over the first side of the second region;
forming a first connecting structure in in the first region, wherein the first connecting structure penetrates the substrate, and the first connecting structure is electrically connected to the device structure;
forming a third electrical connection structure over the second side of the first region, wherein the third electrical connection structure is electrically connected to the first connecting structure; and
forming a second connecting structure in the second region, wherein the second connecting structure is electrically connected to the third electrical connection structure, the second connecting structure extends from the second side to the first side, the second connecting structure penetrates the substrate and the device layer, and the second connecting structure is electrically connected to the second electrical connection structure.

2. The method according to claim 1, wherein:
the device layer includes an isolation structure and the device structure located within the isolation structure, wherein:
the device structure includes a transistor, a capacitor or an inductor; and
the isolation structure is also located over the first side of the second region.

3. The method according to claim 2, further comprising:
forming a first dielectric structure over the isolation structure, wherein:
the first electrical connection structure and the second electrical connection structure are located within the first dielectric structure.

4. The method according to claim 3, further comprising:
forming a second dielectric structure over the second surface of the substrate, wherein:
the third electrical connection structure is located within the second dielectric structure; and
the second connecting structure penetrates the second dielectric structure, the second region, the isolation structure and part of the first dielectric structure.

5. The method according to claim 4, further comprising:
forming a fourth electrical connection structure over the second dielectric structure, wherein:
the fourth electrical connection structure includes a fourth plug and a fourth metal layer located over the fourth plug;
the fourth plug is in contact with the third electrical connection structure; and
the second connecting structure is in contact with the fourth metal layer.

6. The method according to claim 5, wherein a process of forming the second connecting structure and the fourth electrical connection structure includes:
after forming the third electrical connection structure, forming a third dielectric structure over the second dielectric structure;
forming a third groove in the third dielectric structure, the second dielectric structure, the second region, the device layer, and part of the first dielectric structure, wherein a bottom of the third groove exposes a bottom surface of the second electrical connection structure;
forming the second connecting structure in the third groove;
forming the fourth plug in the third dielectric structure; and
forming the fourth metal layer over the fourth plug and the second connecting structure.

7. The method according to claim 1, wherein:
the third electrical connection structure includes a plurality of layers of third plugs and a plurality of layers of third metal layers; and
the plurality of layers of third plugs and the plurality of layers of third metal layers are alternately arranged.

8. The method according to claim 1, wherein:
the first electrical connection structure includes a plurality of layers of first plugs and a plurality of layers of first metal layers, and the plurality of layers of first plugs and the plurality of layers of first metal layers are alternately arranged;
the second electrical connection structure includes a plurality of layers of second metal layers and a second plug located between second metal layers of the plurality of layers of second metal layers; and
the second connecting structure is electrically connected to a second metal layer of the plurality of layers of second metal layers.

9. The method according to claim 1, wherein:
the substrate includes a base and a fin structure located over the base.

10. The method according to claim 1, wherein:
the first connecting structure includes a first portion and a second portion in contact with the first portion;
the first portion extends from the first side of the substrate to the second side of the substrate;
a bottom of the first portion is located in the first region, and a top of the first portion is located in the device layer; and
the second portion extends from the second side of the substrate to the first side of the substrate.

11. The method according to claim 10, wherein a process of forming the first connecting structure includes:
after forming the device layer, forming a first groove in the device layer and the first region, wherein the first groove extends from the first side of the substrate to the second side of the substrate, and a bottom of the first groove is located in the first region;
forming the first portion within the first groove;
after forming the first portion, forming the first electrical connection structure over the device layer, wherein the first electrical connection structure is electrically connected to the first portion;
after forming the first electrical connection structure and the second electrical connection structure, forming a second groove in the first region, wherein the second groove extends from the second side of the substrate to the first side of the substrate, a bottom of the second groove exposes a bottom surface of the first portion; and
forming the second portion in the second groove.

12. A semiconductor structure, comprising:
a substrate, wherein the substrate includes a first side and a second side opposite to the first side, and the substrate includes a first region and a second region;
a device layer located over the first side of the first region, wherein the device layer includes a device structure;
a first electrical connection structure located over the device layer, wherein the first electrical connection structure is electrically connected to the device structure;
a second electrical connection structure located over the first side of the second region;
a first connecting structure located in the first region, wherein the first connecting structure penetrates the substrate and is electrically connected to the device structure;
a third electrical connection structure located on the second side of the first region, wherein the third electrical connection structure is electrically connected to the first connecting structure; and
a second connecting structure located in the second region, wherein the second connecting structure is electrically connected to the third electrical connection structure, the second connecting structure extends from the second side of the substrate to the first side of the substrate, the second connecting structure penetrates the substrate and the device layer, and the second connecting structure is electrically connected to the second electrical connection structure.

13. The semiconductor structure according to claim 12, wherein:
the device layer includes an isolation structure and the device structure located within the isolation structure, wherein the device structure includes a transistor, a capacitor, or an inductor; and
the isolation structure is also located over the first side of the second region.

14. The semiconductor structure according to claim 13, further comprising:
a first dielectric structure located over the isolation structure, wherein the first electrical connection structure and the second electrical connection structure are located in the first dielectric structure; and
a second dielectric structure located over the second side of the substrate, wherein the third electrical connection structure is located within the second dielectric structure, the second connecting structure penetrates the second dielectric structure, the substrate, the device layer, and part of the first dielectric structure.

15. The semiconductor structure according to claim 14, further comprising:
a fourth electrical connection structure located over the second dielectric structure, wherein:
the fourth electrical connection structure includes a fourth plug and a fourth metal layer located over the fourth plug;
the fourth plug is in contact with the third electrical connection structure; and
the second connecting structure is in contact with the fourth metal layer.

16. The semiconductor structure according to claim 12, wherein:
the third electrical connection structure includes a plurality of layers of third plugs and a plurality of layers of third metal layers, and the plurality of layers of the third plugs and the plurality of layers of the third metal layers are alternately arranged.

17. The semiconductor structure according to claim 12, wherein:
the first electrical connection structure includes a plurality of layers of first plugs and a plurality of layers of first metal layers, and the plurality of layers of the first plugs and the plurality of layers of the first metal layers are alternately arranged;
the second electrical connection structure includes a plurality of layers of second metal layers and a second plug located between second metal layers of the plurality of layers of second metal layers; and
the second connecting structure is electrically connected to a second metal layer of the plurality of layers of second metal layers.

18. The semiconductor structure according to claim 12, wherein:
the substrate includes a base and a fin structure located over the base.

19. The semiconductor structure according to claim 12, wherein:
the first connecting structure includes a first portion and a second portion in contact with the first portion;
the first portion extends from the first side of the substrate to the second side of the substrate, a bottom of the first portion is located in the first region, and a top of the first portion is located in the device layer; and
the second portion extends from the second side of the substrate to the first side of the substrate.

20. The semiconductor structure according to claim 12, wherein:
the first connecting structure is made of a material including metal or metal nitride;
the second connecting structure is made of a material including metal or metal nitride;
the metal includes copper, aluminum, tungsten, cobalt, nickel, tantalum, or a combination thereof; and
the metal nitride includes tantalum nitride, titanium nitride, or a combination thereof.
